(19) United States
(12) Patent Application Publication
(10) Pub. No.: US 2010/0323926 A1
(43) Pub. Date: Dec. 23, 2010

(54) DIAGNOSIS DEVICE AND METHOD OF MANUFACTURING THE DIAGNOSIS DEVICE

(75) Inventors: Byoung-Su Lee, Yeosu-si (KR); Do-Young Lee, Seongnam-si (KR)

Correspondence Address: Jae Y. Park, Kile, Park, Goekjian, Reed & McManus, PLLC, 1200 New Hampshire Ave. NW, Suite 570, Washington, DC, 20036, US

(73) Assignee: SILICONFILE TECHNOLOGIES INC., Seoul (KR)

(21) Appl. No.: 12/667,483

(22) PCT Filed: Jul. 15, 2008
(86) PCT No.: PCT/KR2008/004140

§ 371 Date: Dec. 31, 2009

(30) Foreign Application Priority Data
Jul. 18, 2007 (KR) 10-2007-0071428

(51) Int. Cl. C40B 60/12; G03F 7/20; B29D 11/00

(52) U.S. Cl. 506/39; 430/321; 216/24

(57) ABSTRACT

Provided are a diagnosis device in which a bio-chemical reaction between a reference sample and a target sample occurs and a result of the bio-chemical reaction can be detected and a method of manufacturing the diagnosis device. The diagnosis device includes an image sensor where a plurality of photo-detectors are formed; a polymer layer which is made of a polymer material and formed on an upper portion of the image sensor; and a plurality of wells which are formed corresponding to the plurality of photo-detectors on the polymer layer, wherein an inner portion of each well is empty.

### BACKGROUND OF THE INVENTION

1. Field of the Invention

The present invention relates to a diagnosis device, and more particularly, to a diagnosis device in which a bio-chemical reaction portion where bio-chemical reaction between a reference sample and a target sample occurs and a reaction-result detection portion are integrated, wherein the bio-chemical reaction portion is made of a polymer or a glass foil and a method of manufacturing the diagnosis device.

2. Description of the Related Art

In general, a biochip is formed by regularly arraying reference samples constructed with biological molecules such as DNAs and proteins on a substrate made of a glass, a silicon, a metal such as gold, a nylon, or the like. The biochips are classified into a DNA chip and a protein chip according to types of the arrayed reference samples. The biochip basically utilizes a bio-chemical reaction between the reference samples and a target sample fixed on the substrate. As representative examples of the bio-chemical reaction between the reference samples and the target sample, there are a complementary binding between DNA base sequences and an antigen-antibody reaction.

In most cases, diagnosis using the biochip is performed by detecting a degree of the bio-chemical reaction through an optical process. A fluorescence process or a luminescence process is generally used as the optical process.

In an example of an optical process using fluorescence, a fluorescent material is coupled with a target sample applied to a reference sample fixed in a biochip, and the fluorescent material is remained in a specific bio-chemical reaction between the reference sample and the target sample. Next, the fluorescent material emits light under an external light source, and the emitting light is measured.

In an example of an optical process using luminescence, a luminescent material is coupled with a target sample applied to a reference sample fixed in a biochip, and the luminescent material is remained in a specific bio-chemical reaction between the reference sample and the target sample. Next, the luminescent material emits light in a self-emission manner even under no external light source, and the emitting light is measured.

FIG. 1 is a view illustrating a conventional biochip.

Referring to FIG. 1, in the conventional biochip 100, various types of reference samples 120 are arrayed in a predetermined interval on a substrate 1110 made of glass or the like.

When a target sample is applied to various types of reference samples 120 on the conventional biochip 100, a bio-chemical reaction between the target sample and each reference sample 120 occurs. In a case where predetermined amount of fluorescent or luminescent material is included in the target sample through chemical bonding or the like, the fluorescent or luminescent material is remained after the bio-chemical reaction between the target sample and each of the reference samples 120. Similarly, in a case where the luminescent or fluorescent material is generated through a bio-chemical reaction between the target sample and each of the reference samples 120, the fluorescent or luminescent material is remained.

The remaining fluorescent or luminescent material emits light through light illumination or by blocking an external light. The amount of the remaining fluorescent or luminescent material is varied according to a degree of the bio-chemical reaction, so that the amount of light generated from the fluorescent or luminescent material is also varied. In order to measured the amount of generated light, there is needed a separate scanning apparatus such as a CCD camera, a laser scanner, and a high-precision microscope. Since the CCD camera, the laser scanner, the high-precision microscope or the like is very expensive, it is difficult to commercialize the biochip.

FIG. 2 is a view illustrating a CCD camera 210 as an example of a conventional apparatus for scanning a biochip.

In general, an intensity of light generated from the fluorescent material through the illumination or an intensity of light generated from the luminescent material by blocking external light is very weak. Therefore, in a case where a CCD camera 210 is used to detect light generated from the fluorescent or luminescent material, since the CCD camera 210 using a semiconductor is vulnerable to thermal noise, very long exposure time is taken to collect the light generated from the fluorescent or luminescent material, of which intensity is weak. Since the thermal noise is increased in proportion to the exposure time, the detected light includes a large amount of noise, so that a light detecting efficiency may be decreased.

Conventionally, in order to increase the light detecting efficiency of the CCD camera 210, an expensive lens 211 is attached, or the CCD camera 210 is subject to separate treatment. As a representative example of the separate treatment, there is a process of cooling the CCD camera 210. The cooling of the CCD camera 210 leads to a decrease in occurrence of thermal electrons, so that the thermal noise caused from the thermal electrons can be reduced to increase the light detecting efficiency. However, there is a problem in that the cooling process is complicated and requires an additional apparatuses.

### SUMMARY OF THE INVENTION

The present invention provides a diagnosis device having a structure where a bio-chemical reaction portion and a reaction-result detection portion are integrated, wherein the bio-chemical reaction portion is constructed with a polymer or a glass foil.

The present invention also provides a method of manufacturing the diagnosis device.

According to an aspect of the present invention, there is provided a diagnosis device comprising: an image sensor where a plurality of photo-detectors are formed; a polymer layer which is made of a polymer material and formed on an upper portion of the image sensor; and a plurality of wells which are formed corresponding to the plurality of photo-detectors on the polymer layer, wherein an inner portion of each well is empty.

According to another aspect of the present invention, there is provided a diagnosis device comprising: an image sensor where a plurality of photo-detectors are formed; a first photoresist layer which is formed on an upper portion of the image sensor; a second photoresist layer which is formed on an upper portion of the first photoresist layer; and a plurality of wells which are formed corresponding to the plurality of photo-detectors on the second photoresist layer, wherein an inner portion of each well is empty.

According to still another aspect of the present invention, there is provided a diagnosis device comprising: an image sensor where a plurality of photo-detectors are formed; a glass foil which is formed on an upper portion of the image sensor; and a plurality of wells which are formed corresponding to the plurality of photo-detectors on the glass foil, wherein an inner portion of each well is empty.

According to further still another aspect of the present invention, there is provided a method of manufacturing a diagnosis device comprising steps of: forming a first photoresist layer on an upper portion of an image sensor where a plurality of photo-detectors are formed; forming a second photoresist layer on an upper portion of the first photoresist layer; masking an upper portion of the second photoresist layer in a pattern corresponding to the plurality of photo-detectors; and forming a plurality of wells corresponding to the plurality of photo-detectors on the second photoresist layer through exposure and development processes.

According to further still another aspect of the present invention, there is provided a method of manufacturing a diagnosis device comprising steps of: applying a polymer resin on an upper portion of an image sensor where a plurality of photo-detectors are formed; and forming a plurality of wells corresponding to the plurality of photo-detectors by ejecting a solvent of dissolving the polymer resin at a plurality of positions of a surface of the polymer resin corresponding to the plurality of photo-detectors.

According to further still another aspect of the present invention, there is provided a method of manufacturing a diagnosis device comprising: adhering a glass foil on an upper portion of an image sensor wherein a plurality of photo-detectors are formed; coating an upper portion of the glass foil with a photoresist and masking the glass foil in a pattern corresponding to the plurality of photo-detectors; etching the photoresist in the pattern through exposure and development processes; and forming a plurality of wells corresponding to the plurality of photo-detectors by etching the etched portions with a hydrofluoric acid solution.

According to further still another aspect of the present invention, there is provided a method of manufacturing a diagnosis device comprising steps of: adhering a glass foil on an upper portion of an image sensor where a plurality of photo-detectors are formed; applying a polymer resin on an upper portion of the glass foil; etching a portion of the polymer resin by ejecting a solvent of dissolving the polymer resin at a plurality of positions of a surface of the polymer resin corresponding to the plurality of photo-detectors; and forming a plurality of wells corresponding to the plurality of photo-detectors by etching the etched portions with a hydrofluoric acid solution.

According to further still another aspect of the present invention, there is provided a method of manufacturing a diagnosis device comprising steps of: adhering a glass foil on an upper portion of an image sensor where a plurality of photo-detectors are formed; and forming a plurality of wells at a plurality of positions of the glass foil corresponding to the plurality of photo-detectors by using a laser.

### BRIEF DESCRIPTION OF THE DRAWINGS

FIG. 1 is a view illustrating a conventional biochip.

FIG. 2 is a view illustrating a conventional apparatus for scanning a biochip.

FIG. 3 is a view illustrating a diagnosis device according to an embodiment of the present invention.

FIG. 4 is a view illustrating a state that a reference sample is inserted into the diagnosis device illustrated in FIG. 3.

FIG. 5 is a view illustrating a diagnosis device where a plurality of photo-detectors correspond to one well.

FIG. 6 is a view illustrating a diagnosis device where an insulating layer is further formed on an upper portion of an image sensor.

FIG. 7 is a view illustrating a diagnosis device where a color filter and a light-blocking layer are formed in an inner portion of the insulating layer.

FIG. 8 is a view illustrating a diagnosis device where an adhesive layer is further formed on upper portions of the plurality of wells.

FIG. 9 is a view illustrating a diagnosis device according to another embodiment of the present invention.

FIG. 10 is a view illustrating an embodiment of a method of manufacturing the diagnosis device illustrated in FIG. 9.

FIG. 11 is a view illustrating a diagnosis device according to still another embodiment of the present invention.

FIG. 12 is a view illustrating an embodiment of a method of manufacturing the diagnosis device illustrated in FIG. 11.

FIG. 13 is a view illustrating a diagnosis device according to further still another embodiment of the present invention.

FIG. 14 is a view illustrating an embodiment of a method of manufacturing the diagnosis device illustrated in FIG. 13.

FIG. 15 is a view illustrating another embodiment of a method of manufacturing the diagnosis device illustrated in FIG. 13.

FIG. 16 is a view illustrating still another embodiment of a method of manufacturing the diagnosis device illustrated in FIG. 13.

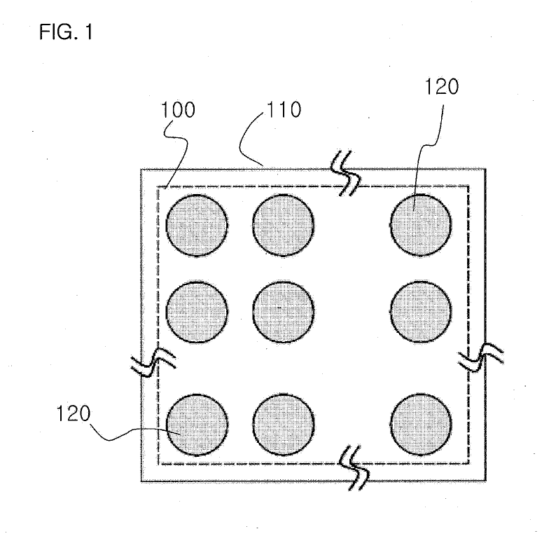

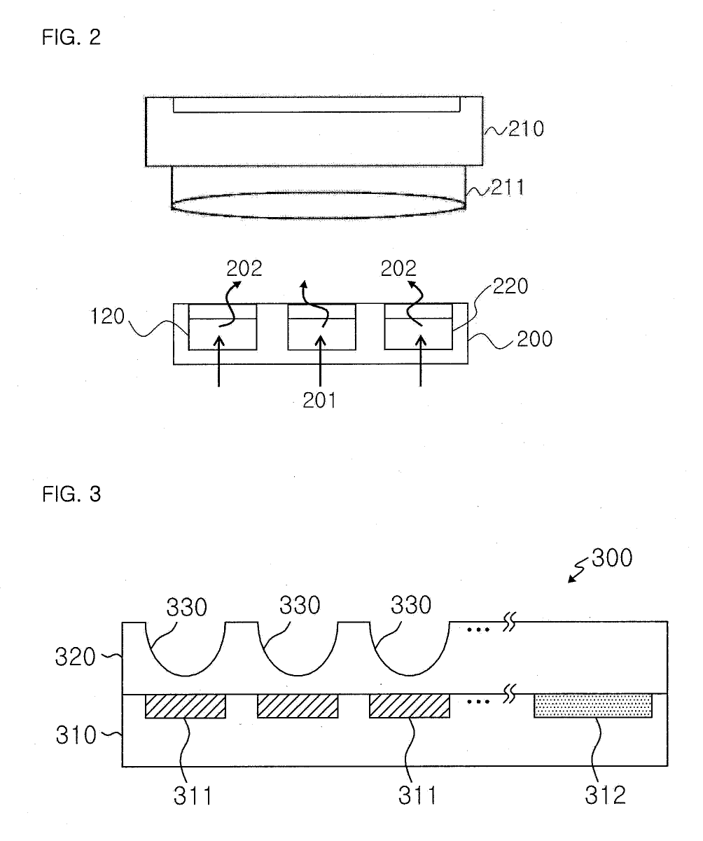

### DETAILED DESCRIPTION OF THE INVENTION

Hereinafter, embodiments of the present invention will be described in detail with reference to the accompanying drawings.

FIG. 3 is a view illustrating a diagnosis device according to an embodiment of the present invention.

The diagnosis device 300 illustrated in FIG. 3 includes an image sensor 310, a polymer layer 320, and a plurality of wells 330.

The image sensor 310 where a plurality of photo-detectors 311 are formed may be a well-known CCD (Charge Coupled Device) or CMOS (Complementary MOS) type image sensor or any types of image sensor. In general, the image sensor 310 is formed on a silicon (Si) substrate which is mainly used for a semiconductor process.

As a representative example of the photo-detectors 311, there are photodiodes. The plurality of photo-detectors 311 that are generally formed on a surface of the image sensor 310 detect light to generate electric charges. Each of the photo-detectors 311 is connected to a peripheral circuit (not shown) for generating a signal corresponding to the generated charges. For example, in case of the CMOS image sensor, the peripheral circuit may be constructed with various circuits including three or four transistors such as a transfer transistor and a reset transistor.

The polymer layer 320 is formed on an upper portion of the image sensor 310. The present invention uses a fluorescence or luminescence phenomenon of a fluorescent or luminescent material which is remained after bio-chemical reaction in the plurality of wells 330 formed in the polymer layer 320. Therefore, it is preferable that the polymer layer 320 is transparent. The polymer layer 320 may be made of a photoresist or a polymer resin such as an epoxy resin.

The plurality of wells 330 are formed in the polymer layer 320 to correspond to the plurality of photo-detectors 311, and an inner portion of each well is empty. The polymer layer 320 and the plurality of wells 330 can be easily formed by performing photoresist coating and, after that, etching through illumination. Alternatively, the polymer layer 320 can be easily formed by applying a polymer resin and ejecting a solvent with an inkjet manner to dissolve the polymer resin. The inner portions of the wells 330 are inserted with various reference samples having a bio-chemical reaction to a target sample.

The target sample which has a bio-chemical reaction to the reference samples in the plurality of wells 330 may include a luminescent material which can spontaneously emits light even when an external light is blocked. In addition, a luminescent material may be generated through a bio-chemical reaction between a target sample and a reference sample in the each well 330. As a representative example of the luminescent material, there is luciferin. The luciferin is activated by ATP (Adenosine Tri-Phosphate) to be an activated luciferin. When the activated luciferin is oxidized by a luciferase to be an oxidized luciferin, a chemical energy is changed into a photon energy, so that light is emitted.

In addition, the target sample having a bio-chemical reaction to the reference sample in an inner portion of each well 330 may include a fluorescent material that emits light under light illumination. As an example of the fluorescent material, there is fluorescence protein (FP) such as Blue FP, Cyan FP, Green FP, and Yellow FP. In addition, a fluorescent material may be generated through a bio-chemical reaction between a target sample and a reference sample in the each well 330.

In the diagnosis device 300 illustrated in FIG. 3, the plurality of wells 330 where the bio-chemical reaction occurs and the plurality of photo-detectors 311 are formed within one apparatus, so that the interval between the plurality of wells 330 and the corresponding photo-detectors 311 can be minimized. Therefore, in the luminescence or fluorescence process of the luminescence or fluorescent material that is remained in each well 330 after the bio-chemical reaction, loss of light can be reduced.

The signal output from the image sensor 310 having the plurality of photo-detectors 311 is processed by an ISP (Image Signal Processor) 312. Referring to FIG. 3, the ISP 312 can be formed together with the image sensor 310 on the substrate. In a case where the ISP 312 together with the image sensor 310 is included in the diagnosis device 300, the diagnosis device 300 can provide a bio-chemical reaction between the target sample and various types of reference samples, sense light which is differently generated according to results of the reaction, and a result of processing.

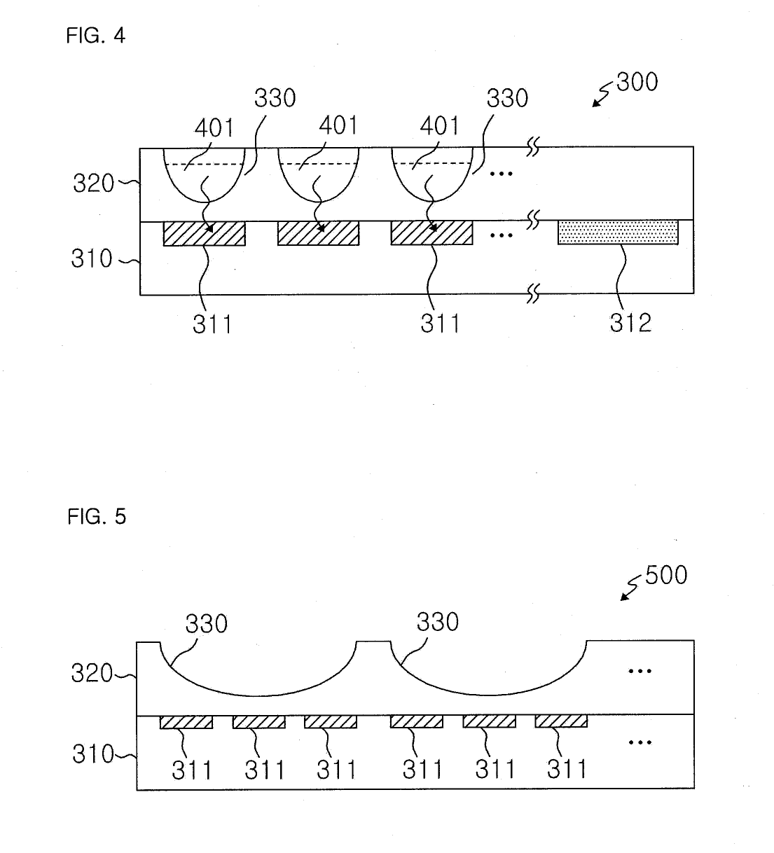

FIG. 4 is a view illustrating a diagnosis device where a reference sample 401 is inserted into the plurality of wells 330 of the diagnosis device 300 illustrated in FIG. 3.

The reference sample 401 may be various types of samples having a bio-chemical reaction to a target sample. The reference sample 401 may be differently determined according to a type of a target bio-chemical reaction in the plurality of wells 330 of the diagnosis device 300. If the bio-chemical reaction is an antigen-antibody reaction, the reference sample 401 may be an antigen. If the bio-chemical reaction is a complementary binding between DNA base sequences, the reference sample 401 may be a gene that is modified for the complementary binding. The target sample that has a bio-chemical reaction to the reference sample 401 is determined according to the reference sample 401. For example, if the reference sample 401 is an antigen, the target sample may be a blood or the like. If the reference sample 401 is a modified gene, the target sample may be a user's gene or the like.

If a degree of bio-chemical reaction between the reference sample 401 and the target sample such as a complementary binding between DNA base sequences or an antigen-antibody reaction is different among the wells 330, a remaining amount of the luminescent material such as luciferin coupled with the target sample may also be different among the wells 330. In order to measure the light emitted from the remaining luminescent material, an external light is blocked. Different intensities of light are emitted from the luminescent material in the wells 330 according to the remaining amount of the luminescent material. Therefore, the intensities of light sensed by the photo-detectors 311 corresponding to the wells 330 are different.

FIG. 5 is a view illustrating a diagnosis device 500 where a plurality of photo-detectors 311 correspond to one well 330. Although one photo-detector 311 may be disposed under one well 330, a plurality of photo-detectors 311 are disposed under one well 330 in order to improve reliability of the light sensing.

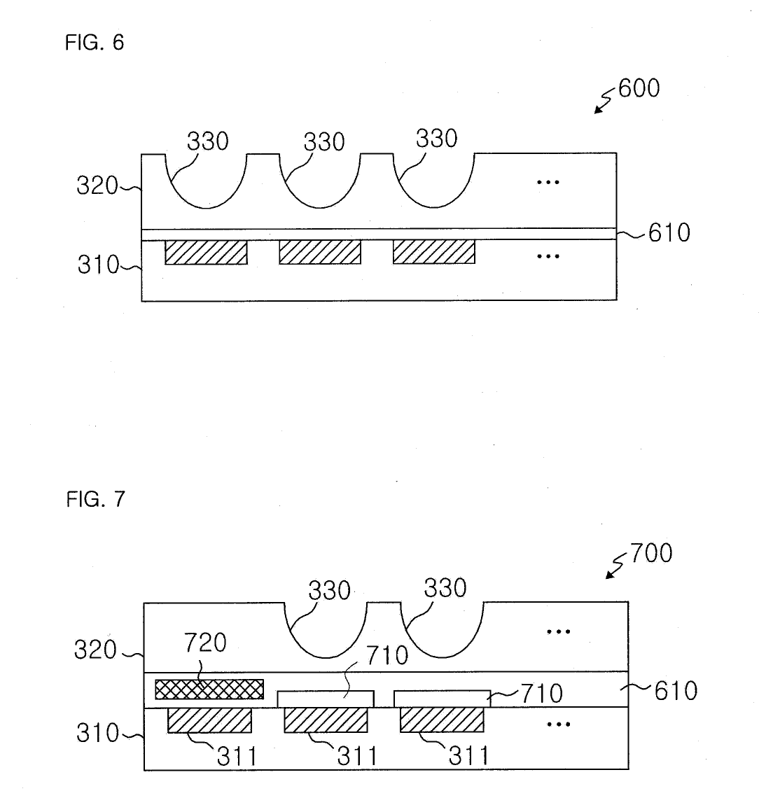

FIG. 6 is a view illustrating a diagnosis device where an insulating layer is further formed on an upper portion of the image sensor.

Referring to FIG. 6, an insulating layer 610 is further formed on an upper portion of the image sensor 310, and the polymer layer 320 is formed on an upper portion of the insulating layer 610. Instead of the insulating layer 610, a passivation layer may be formed in order to protect the photo-detectors 311 formed on the image sensor 310 from external impact or the like.

The insulating layer 610 is preferably made of transparent material so as not to block light incident to the plurality of photo-detectors 311. Namely, the insulating layer 610 may be made of a silicon oxide such as SiO₂, a silicon nitride such as Si₃N₄, or a glass material such as SOG, USG, PSG, BSG, BPSG, and LTO glasses.

FIG. 7 is a view illustrating a diagnosis device where a color filter and a light-blocking layer are formed in an inner portion of the insulating layer.

Referring to FIG. 7, a plurality of color filters 710 corresponding to the plurality of photo-detectors 311 are further formed in an inner portion of the insulating layer 610.

In general, the color filter, that is, an optical filter is needed so as to allow only light having a specific color, that is, in a specific wavelength band to be incident to the photo-detector 311. If the color filter 710 is provided, light in an undesired wavelength band can be prevented form being incident to the photo-detector 311, so that the light sensing efficiency of the plurality of photo-detectors 311 can be improved. The color filter 710 may be formed by spin coating of photoresist or injecting of metal element such as iron (Fe), copper (Cu), cobalt (Co), manganese (Mn), and antimony (Sb). In addition, the color filter 710 may be constructed with a thin film which is formed by using materials having different refractive indices with respect to different wavelengths such as SiO₂, MgF₂, CaF, Al₂O₃, and TiO₂ and changing stacked materials and thicknesses.

For example, if a result of a bio-chemical reaction between the reference sample and the target sample is displayed as a remaining amount of fluorescent material, light illumination is needed so as for the remaining fluorescent material to emit light. Although types of light illumination for fluorescence is varied according to types of fluorescent material, for example, types of FP, blue light or a ultraviolet light is generally used. Therefore, it is preferable that the blue light or ultraviolet light used for light illumination is blocked from being incident to the photo-detectors 311. In a case where the color filter 710 passing only light in a specific wavelength band is used, the light used for light illumination is blocked, and only the light generated from the fluorescent material can be incident to the photo-detectors 311.

Referring to FIG. 7, a light-blocking layer 720 for dark reference may be further formed in an inner portion of the insulating layer 610. The light-blocking layer 720 is formed on an upper portion of at least one of the plurality of photo-detectors 311. In a case where the light-blocking layer 720 is formed, since no light is incident to the photo-detector 311 underlying the light-blocking layer 720, the corresponding photo-detector can be used as the dark reference. The light-blocking layer 720 may be a metal nitride layer such as an aluminum nitride layer, a tungsten nitride layer, and a titanium nitride layer or a black photoresist.

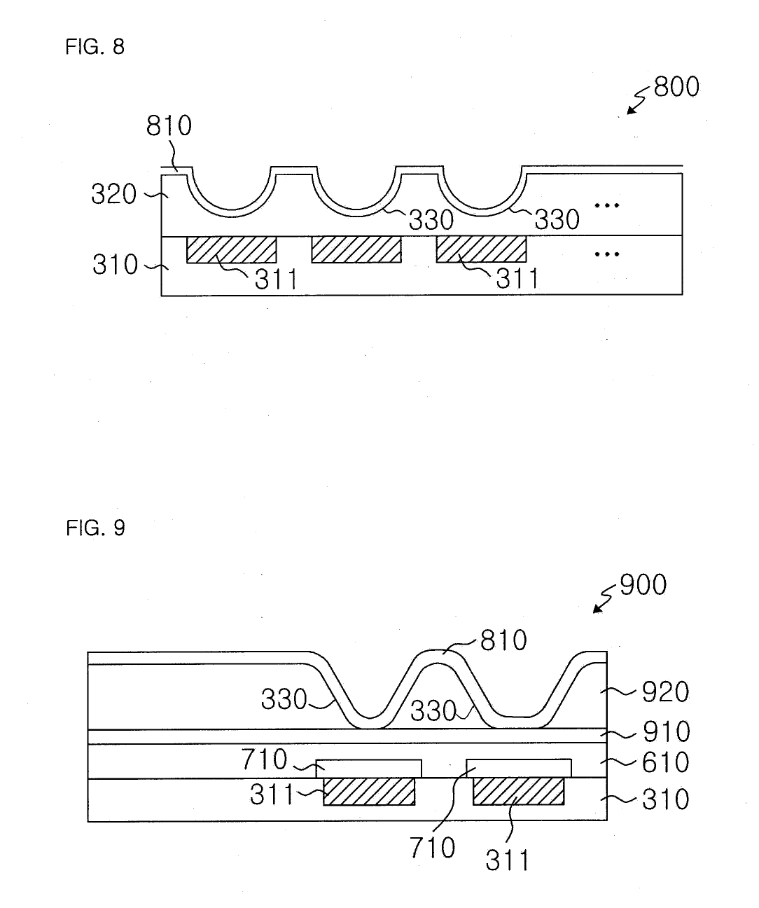

FIG. 8 is a view illustrating a diagnosis device where an adhesive layer is further formed on upper portions of the plurality of wells.

In the diagnosis device 800 illustrated in FIG. 8, an adhesive layer 810 is formed on an upper portion of the plurality of wells 330 formed in the polymer layer 320. In a case where a reference sample is not easily fixed on a polymer but on a different material, if the different material is formed on an upper portion of the well 330, the reference sample can be easily fixed on the plurality of wells 330. The adhesive layer 810 may be made of a silicon oxide such as SiO₂ or a silicon nitride such as Si₃N₄. In addition, the adhesive layer 810 may be made of a photoresist, a polymer compound such as a polymer resin, a chemical such as alginate, and a metal such as gold. These materials can be easily formed on an upper portion of the polymer through a low-temperature process. If the reference sample inserted into the plurality of wells is a peptide which has a good adhesiveness to a silicon oxide, it is preferable that surfaces of the polymer layer 320 and the plurality of wells 330 are coated with a glass such as LTO.

FIG. 9 is a view illustrating a diagnosis device according to another embodiment of the present invention.

In the diagnosis device 900 illustrated in FIG. 9, two types of photoresist layers 910 and 920 are used as the polymer layers. A first photoresist layer PR1 910 is formed on an upper portion of the image sensor 310 and cured. A second photoresist layer PR2 920 is formed on an upper portion of the first photoresist layer 910.

Since the plurality of wells 330 corresponding to the plurality of photo-detectors 311 are formed in the second photoresist layer 920, depths of the wells 330 are also determined according to the thickness of the second photoresist layer 920. Namely, in a case where a large amount of reference sample intends to be inserted into each well 330, the second photoresist layer 920 may be formed to have a relatively large thickness. On the contrary, in a case where a small amount of reference sample intends to be inserted into each well 330, the second photoresist layer 920 may be formed to have a relatively small thickness.

In a case where the second photoresist layer 920 is made of a positive photoresist in which an exposed portion is etched, unmasked portions on the second photoresist layer 920 are etched through exposure and development processes, so that wells 330 are formed. Next, the second photoresist layer 920 is subject to reflow by heating, so that smoothly-slanted wells 330 are formed

Similar to the diagnosis device 800 illustrated in FIG. 8, in the diagnosis device 900 illustrated in FIG. 9, an adhesive layer 810 may be further formed on upper portions of the plurality of wells 330. In addition, similar to the diagnosis devices 600 and 700 illustrated in FIGS. 6 and 7, in the diagnosis device 900 illustrated in FIG. 9, an insulating layer 610 may be further formed on an upper portion of the image sensor 310.

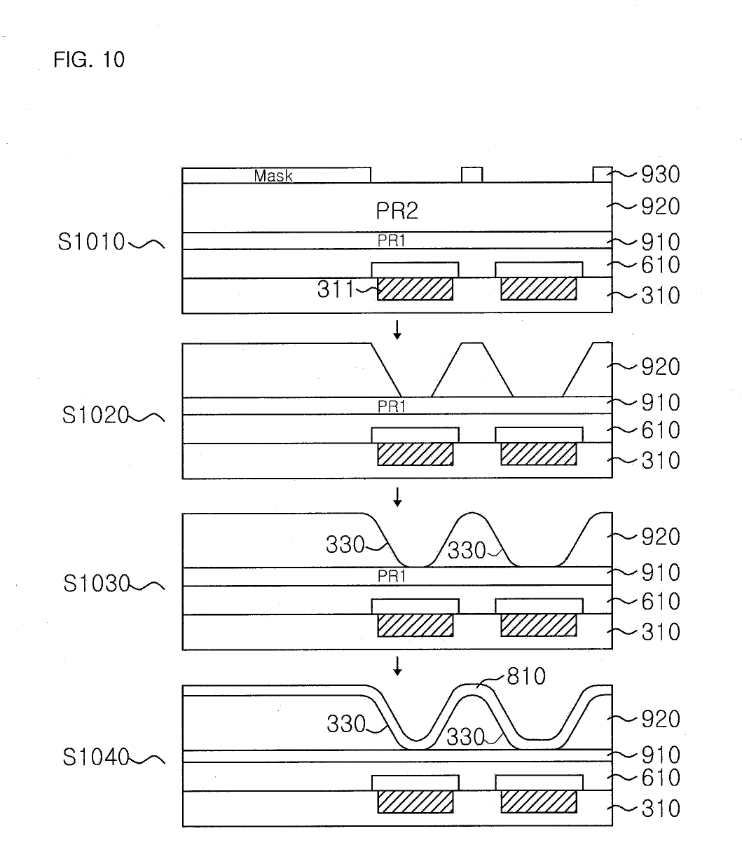

FIG. 10 is a view illustrating an embodiment of a method of manufacturing the diagnosis device illustrated in FIG. 9.

Referring to FIG. 10, the diagnosis device 900 can be manufactured by the following processes.

A first photoresist layer 910 is formed on an upper portion of the image sensor 310 where a plurality of photo-detectors 311 are formed by coating and curing a first photoresist. A second photoresist layer 920 is formed on an upper portion of the first photoresist layer 910 by coating a second photoresist. Exposure and development are performed on the second photoresist layer 920 in a pattern corresponding to the plurality of photo-detectors 311 by using a mask (S1010).

The pattern in the mask 930 corresponding to the plurality of photo-detectors 311 is varied according, to characteristics of the second photoresist layer 920 to light. In a case where the second photoresist layer 920 is made of a positive photoresist where to-be-exposed portions are etched, the to-be-exposed portions are not masked, and the other portions are masked. In this case, at least one of photo-detectors 311 is disposed under the unmasked portion. On the contrary, in a case where the second photoresist layer 920 is made of a negative photoresist where not-to-be-exposed portion are etched, the to-be-exposed portions are masked, and the other portions are not masked. In this case, at least one of photo-detectors 311 is disposed under the masked portion.

The pattern in the mask 930 corresponding to the plurality of photo-detectors 311 is varied according to the number of photo-detectors 311 to which the to-be-formed wells 330 correspond.

In a case where the second photoresist layer 920 is made of a positive photoresist, the exposure and development processes are performed to etch the unmasked portion of the second photoresist layer 920, so that the plurality of wells 330 corresponding to the plurality of photo-detectors 311 are formed (S1020). At this time, the photoresist of the second photoresist layer 920 is subject to reflow by heating, so that smoothly-slanted wells 330 are formed (S1030).

In addition, an adhesive layer 810 may be further formed on upper portions of the plurality of wells 330 so that the reference sample can be easily adhered in the inner portion of the wells 330 (S1040)

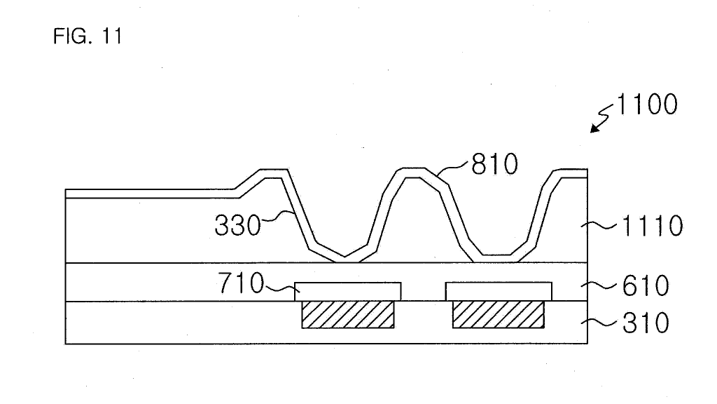

FIG. 11 is a view illustrating a diagnosis device according to still another embodiment of the present invention.

In the diagnosis device 1100 illustrated in FIG. 11, a polymer resin 1110 such as an epoxy resin is used as a polymer layer. The polymer resin 1110 has a property of easily dissolving by a specific solvent. For example, the epoxy resin can be easily dissolved by a polar solvent.

In addition, the polymer resin 1110 that is dissolved by the solvent has a property of aggregating. Therefore, the smoothly-slanted wells 330 can be easily formed.

Similar to the diagnosis device 800 illustrated in FIG. 8, in the diagnosis device 1100 illustrated in FIG. 11, an adhesive layer 810 may be further formed on upper portions of the plurality of wells 330. In addition, similar to the diagnosis devices 600 and 700 illustrated in FIGS. 6 and 7, in the diagnosis device 1100 illustrated in FIG. 11, an insulating layer 610 may be further formed on an upper portion of the image sensor 310.

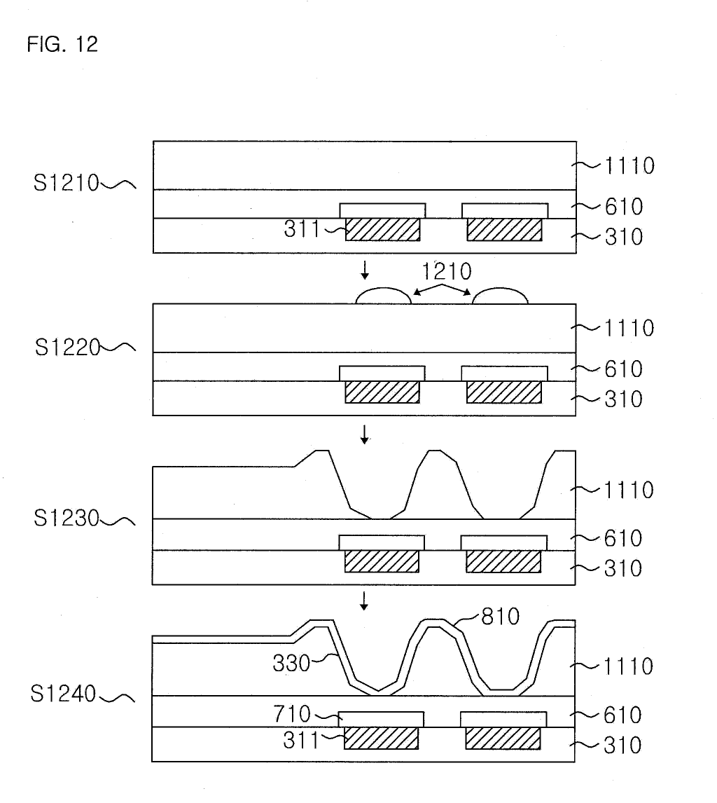

FIG. 12 is a view illustrating an embodiment of a method of manufacturing the diagnosis device illustrated in FIG. 11.

Referring to FIG. 12, the diagnosis device 1100 can be manufactured by the following processes.

A polymer resin 1110 is coated and cured on an upper portion of the image sensor 310 where the plurality of photo-detectors 311 are formed (S1210). A solvent 1210 of dissolving the polymer resin 1110 is ejected at a plurality of positions of a surface of the polymer resin 1110 corresponding to the plurality of photo-detectors 311 (S1220). For example, in a case where the polymer resin 1110 is an epoxy resin, a polar solvent may be used. In this case, the solvent 1210 can be ejected drop by drop on the surface of the polymer resin 1110 through a nozzle in an inkjet manner.

Portion of the polymer resin 1110 that are in contact with the ejected solvent 1210 are dissolved by the solvent, and smoothly-slanted wells 330 are formed due to aggregation property of the dissolved polymer resin (S1230). In addition, an adhesive layer 810 may be further formed on upper portions of the wells 330 so that a reference sample can be easily adhered in inner portions of the wells 330 (S1240).

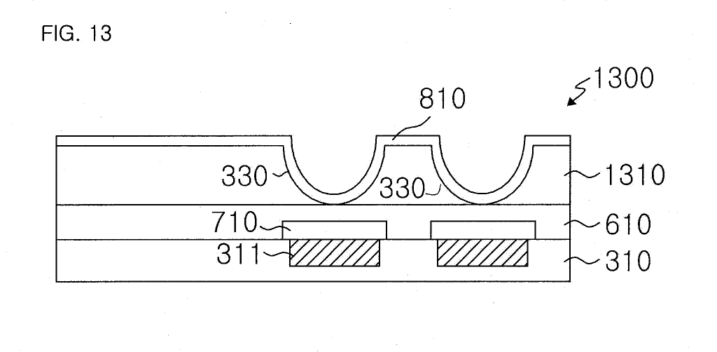

FIG. 13 is a view illustrating a diagnosis device according to further still another embodiment of the present invention.

The diagnosis device 1300 illustrated in FIG. 13 includes an image sensor 310 where a plurality of photo-detectors 311 are formed, a glass foil 1310 which is formed on an upper portion of the image sensor 310, and a plurality of. wells 330 which are formed on the glass foil 1310 corresponding to the plurality of photo-detectors 311, wherein an inner portion is each well is empty. The glass foil 1310 is a flexible glass plate having a thickness of about 10 μl to 200 gm and having a property of being easily adhered to the image sensor 310 and the like. In addition, the glass foil 1310 has a property of being easily etched by a hydrofluoric acid solution.

Similar to the diagnosis device 800 illustrated in FIG. 8, in the diagnosis device 1300 illustrated in FIG. 13, an adhesive layer 810 may be further formed on upper portions of the plurality of wells 330 so that a reference sample can be easily adhered to inner portions of the wells 330. The adhesive layer 810 may be made of a silicon nitride, a polymer compound, a chemical, a metal, or the like. In addition, similar to the diagnosis devices 600 and 700 illustrated in FIGS. 6 and 7, in the diagnosis device 1300 illustrated in FIG. 13, an insulating layer 610 may be further formed on an upper portion of the image sensor 310.

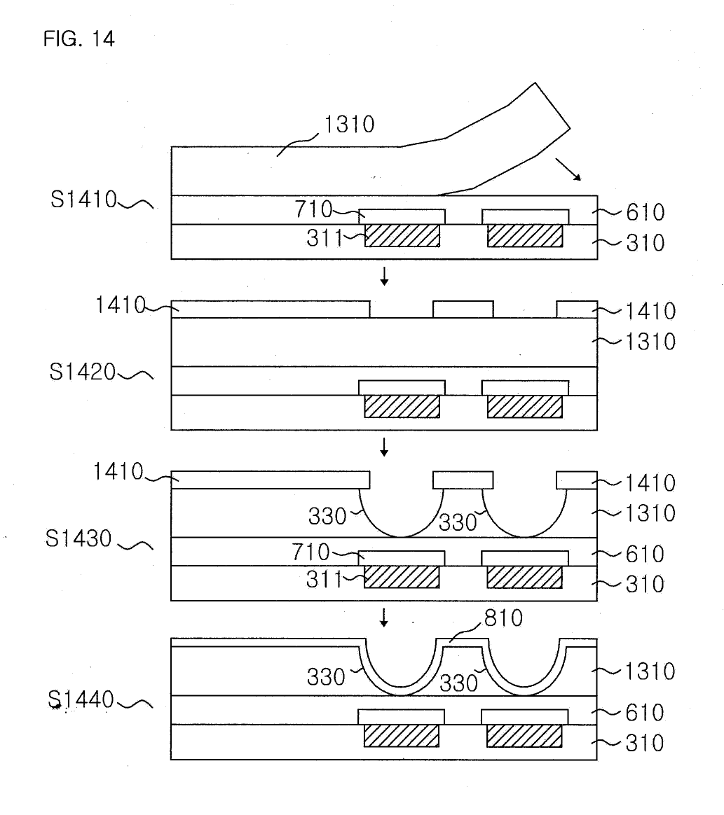

FIG. 14 is a view illustrating an embodiment of a method of manufacturing the diagnosis device illustrated in FIG. 13.

Referring to FIG. 14, the diagnosis device 1300 can be manufactured by the following processes.

Firstly, a glass foil 1310 having a thickness of about 10 μm to 100 μm is adhered to an upper portion of an image sensor 310 where a plurality of photo-detectors 311 are formed (S1410). The glass foil 1310 may be directly adhered on the upper portion of the image sensor 310. Alternatively, after a polymer layer such as photoresist is formed on the upper portion of the image sensor 310, the glass foil 1310 may be adhered on an upper portion of the polymer layer. In order to increase an adhesive force between the glass foil 1310 and the image sensor or between the glass foil 1310 and the polymer layer, thermal treatment may be performed at a temperature of about 50° C. to 150° C. It is preferable that air is not introduced at the time of adhering the glass foil 1310 in any methods.

Next, a photoresist 1410 is coated on an upper portion of the glass foil 1310 and masked in a pattern corresponding to a plurality of photo-detectors 311, and the photoresist 1410 is etched in the pattern through exposure and development processes (S1420).

Next, the etched portions of the photoresist 1410 are etched with a hydrofluoric acid solution so as to form a plurality of wells 330 corresponding to the plurality of photo-detectors 311 (S1430). Next, the photoresist 1410 is removed, and thus, a desired diagnosis device 1300 is obtained.

If needed, an insulating layer 610 may be further formed on an upper portion of the image sensor 310, and the glass foil 1310 may be adhered on an upper portion of the insulating layer 610. In addition, an adhesive layer 810 made of a silicon nitride, a polymer compound, a chemical, a metal, or the like may be further formed on upper portions of the plurality of wells 330 so that a reference sample can be easily adhered to inner portions of the wells 330 (S1440).

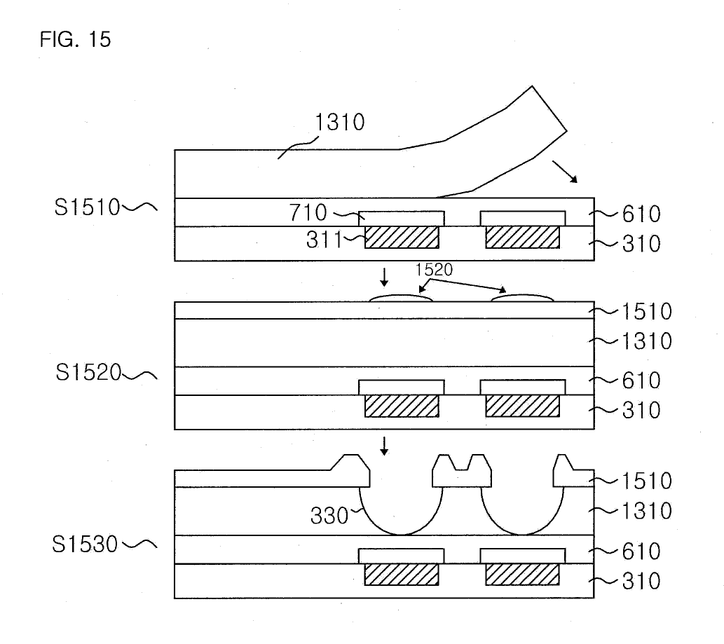

FIG. 15 is a view illustrating another embodiment of a method of manufacturing the diagnosis device illustrated in FIG. 13.

Referring to FIG. 15, the diagnosis device 1300 can be manufactured by the following processes.

Firstly, a glass foil 1310 having a thickness of about 10 μm to 100 μm is adhered to an upper portion of an image sensor 310 where a plurality of photo-detectors 311 are formed (S1510). The method of adhering the glass foil 1310 is the same as described with reference to FIG. 14, and thus, detailed description thereof is omitted.

Next, a polymer resin 1510 is coated on an upper portion of the glass foil 1310, and a solvent 1520 of dissolving the polymer resin 1510 is ejected at a plurality of positions of a surface of the polymer resin 1510 corresponding to the plurality of photo-detectors (S1520). The solvent 1520 may be ejected drop by drop on the surface of the polymer resin 1510 through a nozzle. Portions of the polymer resin 1510 that are in contact with the ejected solvent 1210 are dissolved by the solvent, and thus, the corresponding portions of the polymer resin 1510 are etched.

Next, the etched portions of the polymer resin 1510 are etched with a hydrofluoric acid solution so as to form a plurality of wells 330 corresponding to the plurality of photo-detectors 311. Next, the polymer resin 1410 is removed, and thus, a desired diagnosis device 1300 is obtained.

If needed, an insulating layer 610 may be further formed on an upper portion of the image sensor 310, and the glass foil 1310 may be adhered on an upper portion of the insulating layer 610. In addition, an adhesive layer 810 made of a silicon nitride, a polymer compound, a chemical, a metal, or the like may be further formed on upper portions of the plurality of wells 330 so that a reference sample can be easily adhered to inner portions of the wells 330.

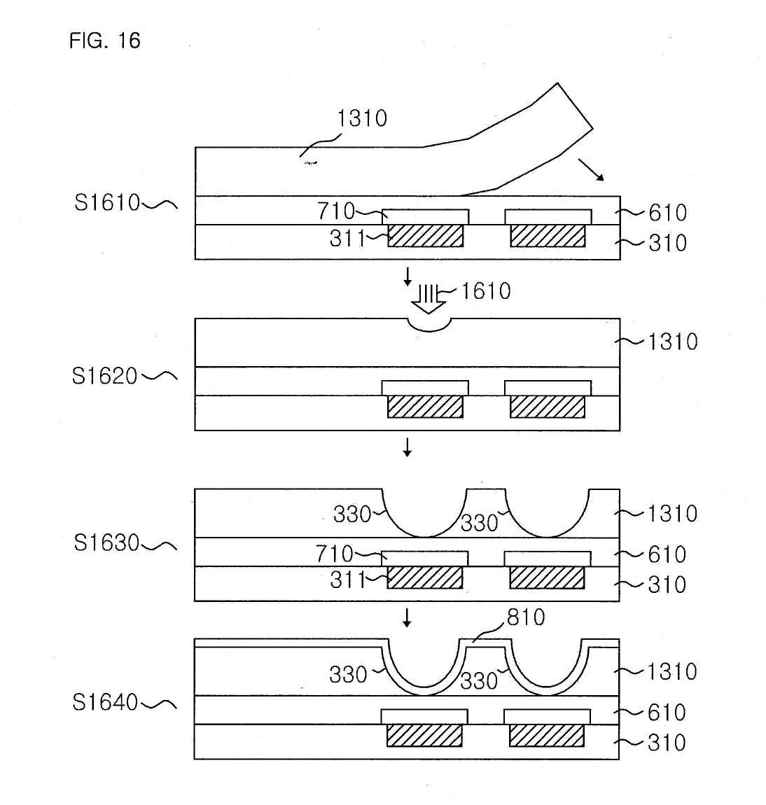

FIG. 16 is a view illustrating still another embodiment of a method of manufacturing the diagnosis device illustrated in FIG. 13.

Referring to FIG. 16, the diagnosis device 1300 can be manufactured by the following processes.

Firstly, a glass foil 1310 having a thickness of about 10 μm to 100 μm is adhered to an upper portion of an image sensor 310 where a plurality of photo-detectors 311 are formed (S1610). The method of adhering the glass foil 1310 is the same as described with reference to FIG. 14, and thus, detailed description thereof is omitted.

Next, upper portions of the glass foil 1310 where the wells 330 are to be formed are illuminated with a laser 1610. The laser may be a CO2 laser or an excimer laser. The portions of the glass foil 1310 illuminated with the laser are evaporated, so that the wells are formed. A depth and size of each well 330 are determined according to illumination time of the laser and a width of laser beam.

If needed, an insulating layer 610 may be further formed on an upper portion of the image sensor 310, and the glass foil 1310 may be adhered on an upper portion of the insulating layer 610. In addition, an adhesive layer 810 made of a silicon nitride, a polymer compound, a chemical, a metal, or the like may be further formed on upper portions of the plurality of wells 330 so that a reference sample can be easily adhered to inner portions of the wells 330.

In a diagnosis device according to the present invention, an interval between a plurality of wells where a bio-chemical reaction occurs and photo-detectors where a degree of the bio-chemical reaction is detected can be minimized, so that it is possible to reduce light loss in a luminescence or fluorescence process.

In addition, in a diagnosis device according to the present invention, additional apparatuses such as a separate CCD camera required by a general biochip are not needed.

In addition, in a diagnosis device according to the present invention, since a plurality of wells where a bio-chemical reaction occurs can be manufactured by using a polymer or a glass foil, it is possible to simplify manufacturing processes and to reduce a production cost of the diagnosis device.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. A diagnosis device comprising:
an image sensor where a plurality of photo-detectors are formed;
a polymer layer which is made of a polymer material and formed on an upper portion of the image sensor; and
a plurality of wells which are formed corresponding to the plurality of photo-detectors on the polymer layer, wherein an inner portion of each well is empty,
wherein the polymer layer is made of a photoresist or a polymer resin.

2. The diagnosis device of claim 1, wherein the plurality of wells are inserted with a reference sample having a bio-chemical reaction to a target sample

3. The diagnosis device of claim 1, wherein at least one photo-detector is disposed under each well.

4. The diagnosis device of claim 1, further comprising an insulating layer which is formed on an upper portion of the image sensor, wherein the polymer layer is formed on an upper portion of the insulating layer.

5. The diagnosis device of claim 1, further comprising an adhesive layer which is formed on upper portions of the plurality of wells.

6. A diagnosis device comprising:
an image sensor where a plurality of photo-detectors are formed;
a first photoresist layer which is formed, on an upper portion of the image sensor;
a second photoresist layer which is formed on an upper portion of the first photoresist layer; and
a plurality of wells which are formed corresponding to the plurality of photo-detectors on the second photoresist layer, wherein an inner portion of each well is empty.

7. The diagnosis device of claim 6, further comprising an adhesive layer which is formed on upper portions of the plurality of wells.

8. The diagnosis device of claim 6, further comprising an insulating layer which is formed on an upper portion of the image sensor, wherein the first photoresist layer is formed on an upper portion of the insulating layer.

9. A diagnosis device comprising:
an image sensor where a plurality of photo-detectors are formed;
a glass foil which is formed on an upper portion of the image sensor; and
a plurality of wells which are formed corresponding to the plurality of photo-detectors on the glass foil, wherein an inner portion of each well is empty.

10. The diagnosis device of claim 9, further comprising an adhesive layer which is formed on upper portions of the plurality of wells.

11. The diagnosis device of claim 9, further comprising an insulating layer which is formed on an upper portion of the image sensor,
wherein the glass foil is formed on an upper portion of the insulating layer.

12. A method of manufacturing a diagnosis device comprising steps of:.
forming a first photoresist layer on an upper portion of an image sensor where a plurality of photo-detectors are formed;
forming a second photoresist layer on an upper portion of the first photoresist layer;
masking an upper portion of the second photoresist layer in a pattern corresponding to the plurality of photo-detectors; and
forming a plurality of wells corresponding to the plurality of photo-detectors on the second photoresist layer through exposure and development processes.

13. The method of claim 12, further comprising a step of reflowing the second photoresist layer by heating after the plurality of wells are formed.

14. The method of claim 12,
wherein an insulating layer is further formed on an upper portion of the image sensor, and
wherein the first photoresist layer is formed on an upper portion of the insulating layer.

15. The method of claim 12, wherein an adhesive layer is further formed on upper portions of the plurality of wells.

16. A method of manufacturing a diagnosis device comprising steps of:
applying a polymer resin on an upper portion of an image sensor where a plurality of photo-detectors are formed; and
forming a plurality of wells corresponding to the plurality of photo-detectors by ejecting a solvent of dissolving the polymer resin at a plurality of positions of a surface of the polymer resin corresponding to the plurality of photo-detectors.

17. The method of claim 16, wherein the solvent is ejected drop by drop on the surface of the polymer resin through a nozzle.

18. The method of claim 16,
wherein an insulating layer is further formed on an upper portion of the image sensor, and
wherein the polymer resin is formed on an upper portion of the insulating layer.

19. The method of claim 16, wherein an adhesive layer is further formed on upper portions of the plurality of wells.

20. A method of manufacturing a diagnosis device comprising:
adhering a glass foil on an upper portion of an image sensor wherein a plurality of photo-detectors are formed;
coating an upper portion of the glass foil with a photoresist and masking the glass foil in a pattern corresponding to the plurality of photo-detectors;
etching the photoresist in the pattern through exposure and development processes; and
forming a plurality of wells corresponding to the plurality of photo-detectors by etching the etched portions with a hydrofluoric acid solution.

21. The method of claim 20, wherein the step of adhering the glass foil on the upper portion of the image sensor wherein the plurality of photo-detectors are formed is a step of;
further forming an insulating layer on an upper portion of the image sensor; and
adhering the glass foil on an upper portion of the insulating layer.

22. The method of claim 20, wherein an adhesive layer is further formed on upper portions of the plurality of wells.

23. The method of claim 20, wherein the step of adhering the glass foil on the upper portion of the image sensor wherein the plurality of photo-detectors are formed is a step of;
further forming an polymer layer on an upper portion of the image sensor; and
adhering the glass foil on an upper portion of the polymer layer.

24. A method of manufacturing a diagnosis device comprising steps of:
adhering a glass foil on an upper portion of an image sensor where a plurality of photo-detectors are formed;
applying a polymer resin on an upper portion of the glass foil;
etching a portion of the polymer resin by ejecting a solvent of dissolving the polymer resin at a plurality of positions of a surface of the polymer resin corresponding to the plurality of photo-detectors; and
forming a plurality of wells corresponding to the plurality of photo-detectors by etching the etched portions with a hydrofluoric acid solution.

25. The method of claim 24, wherein the solvent is ejected drop by drop on the surface of the polymer resin through a nozzle.

26. The method of claim 24, wherein adhering the glass foil on the upper portion of the image sensor where the plurality of photo-detectors are formed is a step of:
further forming an insulating layer on an upper portion of the image sensor; and
adhering the glass foil on an upper portion of the insulating layer.

27. The method of claim 24, wherein an adhesive layer is further formed on upper portions of the plurality of wells.

28. The method of claim 24, wherein the step of adhering the glass foil on the upper portion of the image sensor wherein the plurality of photo-detectors are formed is a step of;
further forming an polymer layer on an upper portion of the image sensor; and
adhering the glass foil on an upper portion of the polymer layer.

29. A method of manufacturing a diagnosis device comprising steps of:
adhering a glass foil on an upper portion of an image sensor where a plurality of photo-detectors are formed; and
forming a plurality of wells at a plurality of positions of the glass foil corresponding to the plurality of photo-detectors by using a laser.

30. The method of claim 29, wherein the laser is a CO₂ laser or an Excimer laser.

31. The method of claim 29, wherein adhering the glass foil on the upper portion of the image sensor where the plurality of photo-detectors are formed is a step of:
further forming an insulating layer on an upper portion of the image sensor; and
adhering the glass foil on an upper portion of the insulating layer.

32. The method of claim 29, wherein an adhesive layer is further formed on upper portions of the plurality of wells.

33. The method of claim 29, wherein the step of adhering the glass foil on the upper portion of the image sensor where the plurality of photo-detectors are formed is a step of;
further forming an polymer layer on an upper portion of the image sensor; and
adhering the glass foil on an upper portion of the polymer layer.
